(19) United States
(12) Patent Application Publication
(10) Pub. No.: US 2024/0258164 A1
(43) Pub. Date: Aug. 1, 2024

(54) METHODS OF FORMING INTERCONNECT STRUCTURES

(71) Applicant: Applied Materials, Inc., Santa Clara, CA (US)

(72) Inventors: Jiajie Cen, San Jose, CA (US); Carmen Leal Cervantes, Mountain View, CA (US); Yong Jin Kim, Albany, CA (US); Kevin Kashefi, San Ramon, CA (US); Xiaodong Wang, San Jose, CA (US)

(73) Assignee: Applied Materials, Inc., Santa Clara, CA (US)

(21) Appl. No.: 18/418,786

(22) Filed: Jan. 22, 2024

Related U.S. Application Data
(60) Provisional application No. 63/482,052, filed on Jan. 29, 2023.

(51) Int. Cl. H01L 21/768; H01L 21/02

(52) U.S. Cl. CPC H01L 21/76844; H01L 21/02063

(57) ABSTRACT

Methods of forming devices comprise forming a dielectric layer on a substrate, the dielectric layer comprising at least one feature defining a gap including sidewalls and a bottom. A pre-clean process is performed before a self-assembled monolayer (SAM) is formed on the bottom of the gap. A barrier layer is selectively deposited on the sidewalls but not on the bottom of the gap. The SAM is removed after selectively depositing the barrier layer on the sidewalls.

### CROSS-REFERENCE TO RELATED APPLICATIONS

The present application claims priority to U.S. provisional patent application No. 63/482,052 filed on Jan. 29, 2023, the entire content of which is incorporated herein by reference.

### TECHNICAL FIELD

Embodiments of the disclosure generally relate to methods of forming interconnect structures in microelectronic devices. More particularly, embodiments of the disclosure are directed to methods of improving selective deposition of metal on dielectric surfaces during formation of interconnect structures in microelectronic devices.

### BACKGROUND

Multiple challenges impede power and performance improvements when scaling transistors and interconnects to the 3 nm node and beyond. Interconnects include metal lines that transfer current within the same device layer and metal vias that transfer current between layers. Pitch reduction narrows the width of both and increases resistance, and also increases the voltage drop across a circuit, throttling circuit speed and increasing power dissipation.

While transistor performance improves with scaling, the same cannot be said for interconnect metals. As dimensions shrink, interconnect via resistance can increase by a factor of 10. An increase in interconnect via resistance may result in resistive-capacitive (RC) delays that reduce performance and increases power consumption. A conventional copper interconnect structure includes a barrier layer deposited on the sidewalls of gap that provide a via the sidewalls made of a dielectric material, providing good adhesion and preventing the copper from diffusing into the dielectric layer and other adverse interactions between the dielectric layers and may also include a metal liner deposited on the barrier layer. When present, a metal liner deposited on the barrier layer adheres to the barrier layer and facilitates subsequent copper (Cu) fill in a gap between the sidewalls. Copper is deposited into the remaining volume of the gap. Barrier layers can typically be the largest contributor to via resistance due to high resistivity. Past approaches have focused on reducing the thickness of barrier layers or finding barrier layers with lower resistivity to decrease via resistance. Increased via resistance remains an issue, especially in smaller features when barrier layers on sidewalls form an increasing percentage of the via volume. Accordingly, there is a need for methods for depositing material layers during formation of interconnect structures that improve performance of interconnects.

### SUMMARY

Embodiments of the disclosure are directed to methods of forming a microelectronic device. In one or more embodiments, the methods comprise forming a dielectric layer on a substrate, the dielectric layer comprising at least one feature defining a gap including sidewalls and a bottom including a metal surface; pre-cleaning the metal surface; selectively depositing a self-assembled monolayer (SAM) on the bottom of the gap and the metal surface; selectively depositing a barrier layer on the sidewalls but not on the metal surface; and removing the SAM after selectively depositing the barrier layer on the sidewalls.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A illustrates a portion of a microelectronic device during a stage of manufacture with one or more embodiments of the disclosure having a metal surface containing impurities on a bottom of a gap;

FIG. 1B illustrates removal of the impurities from the metal surface shown in FIG. 1A;

FIG. 1C illustrates deposition of a self-assembled monolayer on the metal surface shown in FIG. 1B;

FIG. 1D illustrates a barrier layer formed on the sidewalls of the gap;

FIG. 1E illustrates removal of the self-assembled monolayer in FIG. 1D; and

FIG. 2 illustrates a process flow diagram of a method of manufacturing a microelectronic device in accordance with one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used.

As used in this specification and the appended claims, the terms “reactive gas”, “precursor”, “reactant”, and the like, are used interchangeably to mean a gas that includes a species which is reactive with a substrate surface. For example, a first “reactive gas” may simply adsorb onto the surface of a substrate and be available for further chemical reaction with a second reactive gas.

Some embodiments of the disclosure provide methods for improving performance of interconnects. Interconnects comprise metal lines that transfer current within the same device layer, and metal vias that transfer current between layers. These lines and vias are formed with conductive metal such as copper or cobalt in gaps formed within the device. In one or more embodiments, a dielectric layer comprises at least one feature defining a gap including sidewalls and a bottom. In one or more embodiments, the gap comprises the metal lines and the metal vias. In one or more embodiments, the metal lines have a sidewall and a bottom. In one or more embodiments, the metal vias have a sidewall and a bottom. As used in this specification and the appended claims, unless specified otherwise, reference to the “bottom of the gap” is intended to mean the bottom of the metal via, which is nearest the substrate.

As the technology node advances, for example, when scaling microelectronic devices and interconnects to the 3 nm node and beyond the back end of line (BEOL) includes new interfaces such as tungsten (W), molybdenum (Mo), and ruthenium (Ru). Improving self-assembled monolayer (SAM) selectivity on metal to low-k surfaces becomes more challenging, especially when these interfaces contain different kinds of impurities such as oxygen, carbon, nitrogen, fluorine, chlorine, etc. It has been determined that the pre-clean before SAM processes becomes very critical to further improve SAM selectivity. This helps control damage to low K dielectric materials.

Embodiments of the disclosure provide methods of forming interconnect structures in the manufacture of microelectronic devices. In one or more embodiments, microelectronic devices described herein comprise at least one top interconnect structure that is interconnected to at least one bottom interconnect structure. Embodiments of the disclosure provide microelectronic devices and methods of manufacturing microelectronic devices that improve performance of interconnects, for example, reducing via resistance.

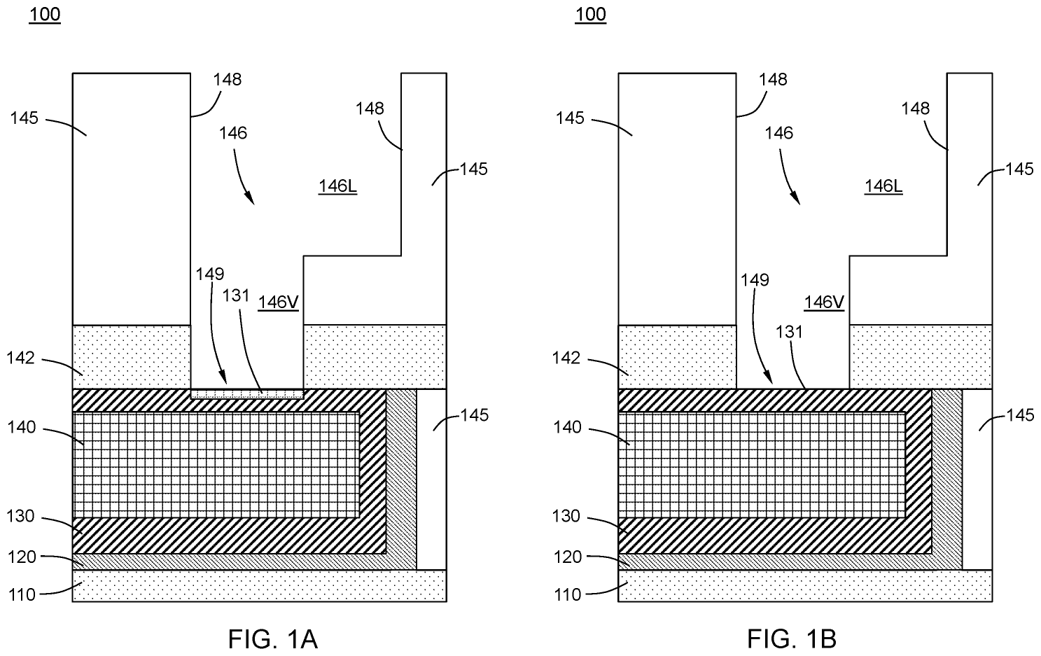

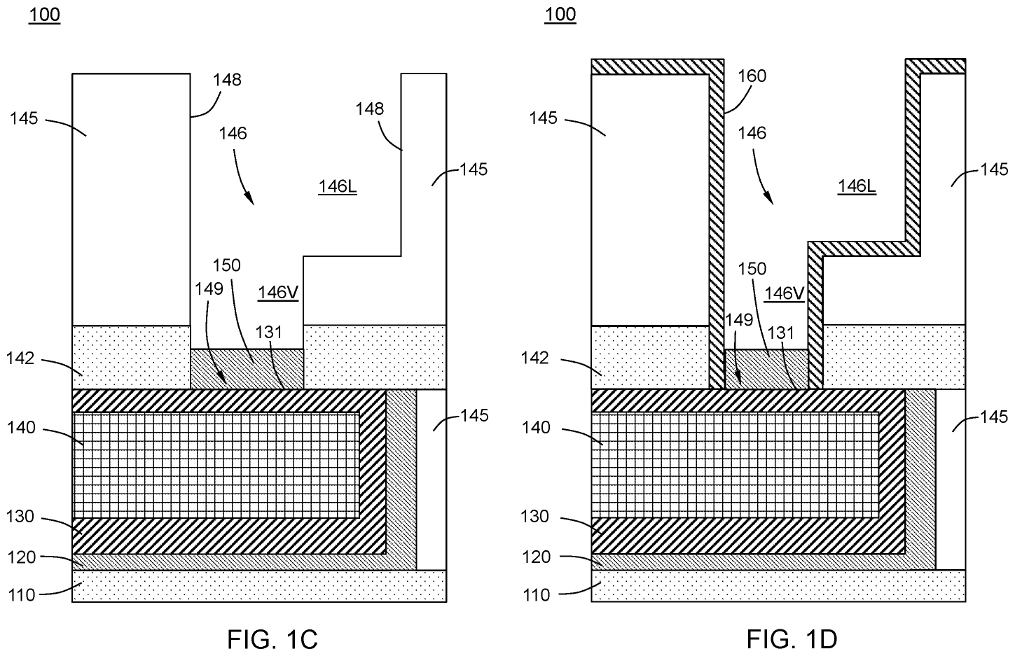

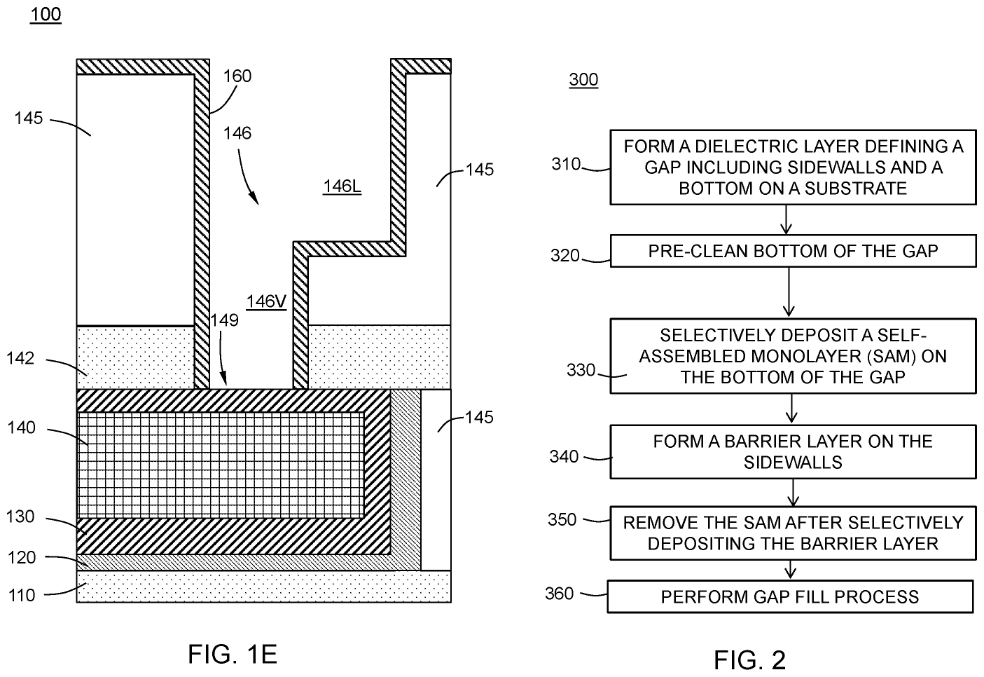

Methods of forming microelectronic devices are described herein with reference to FIGS. 1A-1E. FIG. 2 is a flow chart of an exemplary method of forming microelectronic devices with respect to FIGS. 1A-1E.

Referring to FIGS. 1A-1E, a portion of a microelectronic device 100 is shown during stages of manufacture, where the substrate is a substrate processing chamber, such as an atomic layer deposition processing chamber, a chemical vapor deposition processing chamber, a cyclical vapor deposition chamber, or a preclean chamber. In one or more embodiments, the substrate processing chamber comprises a local plasma source, a remote plasma source or both a local plasma source or a remote plasma source. The plasma source in some embodiments comprise an inductively coupled plasma source or a capacitively coupled plasma source. The plasma sources include one or more of a hydrogen, argon, H₂O, ammonia, neon, krypton, or helium gas supply.

During plasma treatment pressure in the substrate processing chamber in some embodiments, is from 0.1 mTorr to 10 Torr. The plasma in some embodiments comprises an inductively coupled plasma (ICP) and/or a capacitively coupled plasma (CCP) with or without an ion filter.

In one aspect, methods comprise forming a dielectric layer on a substrate, the dielectric layer comprising at least one feature defining a gap including sidewalls and a bottom including a metal surface, pre-cleaning the metal surface, selectively depositing a self-assembled monolayer (SAM) on the bottom of the gap and the metal surface, selectively depositing a barrier layer on the sidewalls but not on the metal surface, and removing the SAM after selectively depositing the barrier layer on the sidewalls.

In FIG. 1A, the microelectronic device 100 comprises a substrate 110, a barrier layer 120 on the substrate 110, a conductive filled gap 140, an aluminum oxide etch stop layer 142, a dielectric layer 145 on the aluminum oxide etch stop layer 142, the dielectric layer 145 comprising at least one feature defining a gap 146 including sidewalls 148 and a bottom 149. According to one or more embodiments, a metal surface 131 containing impurities is on the bottom 149 of the gap. It will be appreciated that in one or more embodiments, the conductive filled gap 140 forms a metal line that transfers current within the same device layer.

In one or more embodiments, the substrate 110 is a wafer, for example a semiconductor substrate. In one or more embodiments, the substrate 110 is an etch stop layer on a wafer. In one or more embodiments, the substrate 110 is an aluminum oxide etch stop layer on a wafer. In one or more embodiments, the barrier layer 120 comprises tantalum nitride (TaN) or doped TaN. In one or more embodiments, the barrier layer 120 comprises tantalum nitride (TaN) formed by ALD. In one or more embodiments, the conductive filled gap 140 comprises one or more of copper (Cu) or cobalt (Co). In one or more embodiments, the etch stop layer 142 comprises one or more of aluminum oxide, silicon nitride and aluminum nitride.

In one or more embodiments, the dielectric layer 145 is a low-k dielectric layer. In certain embodiments, the dielectric layer 145 comprises silicon oxide (SiOₓ). In one or more embodiments, the dielectric layer 145 comprises SiOₓH_{y}(CH_{z}). Further embodiments provide that the dielectric layer 145 comprises porous or carbon-doped SiOₓ. In some embodiments, the dielectric layer 145 is a porous or carbon-doped SiOₓ layer with a k value less than about 5. In other embodiments, the dielectric layer 145 is a multilayer structure. For example, in one or more embodiments, the dielectric layer 145 comprises a multilayer structure having one or more of a dielectric layer, an etch stop layer, and a hard mask layer.

In one or more embodiments, the dielectric layer 145 comprises at least one feature defining a gap 146 including sidewalls 148 and a bottom 149. The Figures show substrates having a single feature for illustrative purposes, however, those skilled in the art will understand that there can be more than one feature. The shape of the feature can be any suitable shape including, but not limited to, trenches, cylindrical vias that, when filled with metal, transfer current between layers, and lines that transfer current within the same device layer. In some embodiments, the feature defines a gap 146 in the dielectric layer 145. The gap 146 in some embodiments defines a via portion 146V and a line portion 146L, but the embodiments shown are not intended to be limiting. As used herein, the term “feature” means any intentional surface irregularity. Suitable examples of features include but are not limited to trenches which have a top, two sidewalls and a bottom, peaks which have a top and two sidewalls. Features can have any suitable aspect ratio (ratio of the depth of the feature to the width of the feature). In some embodiments, the aspect ratio is greater than or equal to about 5:1, 10:1, 15:1, 20:1, 25:1, 30:1, 35:1 or 40:1.

Referring to FIG. 1B, the metal surface has been cleaned by exposing the metal surface 131 at the bottom 149 of the gap to a cleaning gas. As discussed above, in embodiments, the substrate is in a substrate processing chamber and the pre-cleaning process comprises exposing the metal surface to a cleaning gas selected from H₂O vapor, H₂O₂, WF₆, NH₃, MoCl₅, MoCl₆, WCl₅, WCl₆, SOCl₂, PCl₅ when the temperature in the substrate processing chamber is at or above 80° C., at or above 100° C., at or above 120° C., at or above 140° C., at or above 160° C., at or above 180° C., or at or above 200° C. In some embodiments, the temperature is in a range with an upper temperature value of to 450° C. After or during exposing the metal surface to the cleaning gas, the method further comprises exposing the metal surface to a plasma. Exposing the metal surface to a cleaning gas and to the plasma reduces impurities from the metal surface. The impurities on the metal surface according to embodiments include but are not limited to impurities selected from the group consisting of F, Cl, O, N, and C.

In embodiments in which metal surface comprises tungsten, the cleaning gas is selected from H₂O vapor, H₂O₂, WF₆ and exposing metal surface to the cleaning gas occurs for a time from 1 second to 240 seconds, 2 seconds to 120 seconds, 5-90 seconds or 10-40 seconds for a time sufficient to reduce the impurities. In embodiments in which the metal surface comprises molybdenum, the cleaning gas is selected from NH₃, NH₄OH, MoCl₅, MoCl₆, WCl₅, WCl₆, SOCl₂ and exposing metal surface to the cleaning gas occurs for a time from 1 second to 240 seconds, 2 to 120 seconds, 5-90 seconds or 10-40 seconds for a time sufficient to reduce the impurities.

After exposing the metal surface to the cleaning gas with the processing chamber at an elevated temperature at or above 80° C., at or above 100° C., at or above 120° C., at or above 140° C., at or above 160° C., at or above 180° C., or at or above 200° C. In some embodiments, the temperature is in a range with an upper temperature value of to 450° C.

Referring to FIG. 1C, a passivation layer (e.g., a self-assembled monolayer (SAM)) 150 is on the metal surface In one or more embodiments, the SAM 150 is formed on the metal surface 131 that has been pre-cleaned. In one or more embodiments, the SAM 150 is deposited by exposing the bottom 149 of the gap to a hydrocarbon carried in an inert carrier gas, for example, argon (Ar) gas. In one or more embodiments, the SAM 150 comprises a silane or an unsaturated hydrocarbon. The SAM blocks deposition of the barrier layer on the metal surface. In some embodiments, the pre-cleaning and the plasma prior to deposition of the SAM results in 100% blocking of deposition of the barrier layer on the metal surface. The barrier layer in some embodiments comprises tantalum nitride (TaN) or ruthenium (Ru) and or other doped TaN layer.

In some embodiments, selectively depositing the SAM comprises exposing the bottom of the gap to a silane or a hydrocarbon having the formula R₁—C≡C—R₂ or H—C≡C—R₃, wherein R1 and R2 can be the same of different and R1 and R2 are linear alkyl chains having from 1 to 15 carbon atoms and R3 is a linear alkyl chain comprising from 1 to 20 carbon atoms. In specific embodiments, the silane has a formula R—SiH₃, wherein R is selected from a linear alkyl chain and a branched alkyl chain comprising from 2 to 20 carbon atoms. In other specific embodiments, the hydrocarbon has the formula R₁—C≡C—R₂. In one specific embodiment, the hydrocarbon is 5-decyne. In other specific embodiments, the hydrocarbon has the formula H—C≡C—R₃—.

In some embodiments, the substrate is soaked in a vapor of the unsaturated hydrocarbon or the silane. In some embodiments, the processing conditions for exposing the substrate to the unsaturated hydrocarbon or the silane may be controlled.

In some embodiments, the pressure of the processing chamber is controlled. The pressure of the processing chamber may be any suitable pressure for forming the blocking layer. In some embodiments, the pressure of the processing chamber is maintained at less than or equal to about 80 Torr, less than or equal to about 70 Torr, less than or equal to about 60 Torr, less than or equal to about 50 Torr, less than or equal to about 40 Torr, less than or equal to about 30 Torr, less than or equal to about 20 Torr, less than or equal to about 15 Torr, less than or equal to about 10 Torr, or less than or equal to about 5 Torr. In some embodiments, the pressure of the processing chamber is maintained at about 10 Torr, about 20 Torr, about 30 Torr, about 40 Torr, or about 50 Torr.

In one or more embodiments, a flow of argon (Ar) gas is configured to carry the unsaturated hydrocarbon or the silane from a container to the processing chamber. In some embodiments, the flow rate of the argon (Ar) gas that is configured to carry the unsaturated hydrocarbon or the silane into the processing chamber is controlled. The flow rate of the argon (Ar) gas may be any suitable flow rate for forming the passivation layer. In some embodiments, the flow rate of the argon (Ar) gas is in a range of about 50 sccm to about 100 sccm, or in a range of about 75 sccm to about 100 sccm. In one or more embodiments, the flow rate of the argon (Ar) gas is about 600 sccm. In some embodiments, the flow rate of the argon (Ar) gas is less than or equal to about 600 sccm, less than or equal to about 500 sccm, less than or equal to about 400 sccm, less than or equal to about 300 sccm, less than or equal to about 250 sccm, less than or equal to about 200 sccm, less than or equal to about 150 sccm, less than or equal to about 100 sccm, less than or equal to about 75 sccm, or less than or equal to about 50 sccm.

In some embodiments, the soak period, during which the unsaturated hydrocarbon or the silane is exposed to the substrate, is controlled. The soak period may be any suitable period for forming the blocking layer. In some embodiments, the soak period is greater than or equal to about 10 s, greater than or equal to about 20 s, greater than or equal to about 30 s, greater than or equal to about 45 s, greater than or equal to about 60 s, greater than or equal to about 80 s, greater than or equal to about 120 s, greater than or equal to about 150 s, or greater than or equal to about 200 s. In some embodiments, the soak period is about 60 s. In some embodiments, the soak period is about 200 s.

In one or more embodiments, the unsaturated hydrocarbon or the silane is in a liquid phase when the unsaturated hydrocarbon or the silane is in a container, such as an ampoule or a cylinder, from which the unsaturated hydrocarbon or the silane is delivered to the chamber in a carrier gas. In some embodiments, the unsaturated hydrocarbon or the silane is in a saturated vapor phase in the container when the container has a pressure of about 0.1 torr. In one or more embodiments, a temperature of the container is lower than the temperature in the processing chamber. In one or more embodiments, a carrier gas such as argon (Ar) gas carries the saturated vapor phase unsaturated hydrocarbon or the silane from the container to the processing chamber. In some embodiments, a temperature of the processing chamber is controlled during exposure to the unsaturated hydrocarbon or the silane. The temperature of the processing chamber may also be referred to as the operating temperature. In some embodiments, the temperature of the processing chamber is in a range of about 200° C. to about 450° C. In some embodiments, the temperature of the processing chamber is less than or equal to about 300° C., less than or equal to about 275° C., less than or equal to about 250° C., less than or equal to about 225° C., or less than or equal to about 200° C.

Referring to FIG. 1D, a barrier layer 160 is shown on the SAM 150 and over the sidewalls 148. In one or more embodiments, the barrier layer 160 has the same properties as the barrier layer 120. In one or more embodiments, when the SAM 150 is not present, the deposition of the barrier layer 160 is substantially conformal. As used herein, a layer which is “substantially conformal” refers to a layer where the thickness is about the same throughout (e.g., on the top, middle and bottom of sidewalls 148 and on the bottom 149 of the gap 146). A layer which is substantially conformal varies in thickness by less than or equal to about 5%, 2%, 1% or 0.5%.

In one or more embodiments, the barrier layer 160 forms on the sidewalls 148 and is substantially prevented from forming on the metal surface 131 at the bottom 149 of the gap 146. In one or more embodiments, the barrier layer 160 forms on the sidewalls 148 but does not form on the metal surface 131 at the bottom 149 of the gap 146. In some embodiments, the pre-clean process following by the SAM completely blocks formation of the barrier layer 160 on the metal surface 131 at the bottom of the gap 146, and no barrier layer 160 material is deposited on the metal surface. In one or more embodiments, the barrier layer 160 is selectively deposited on at least a portion of the sidewalls 148. In one or more embodiments, the barrier layer 160 may cover the entirety of the sidewalls 148.

One of more embodiments of the disclosure including the pre-cleaning described herein provides special surface modification of the metal surface 131 to further improve SAM selectivity. The thermal soak and plasma treatments described herein improve the selectivity. Embodiments significantly improve the SAM selectivity and eliminate the formation of a TaN barrier layer or Ru barrier layer thickness on the metal surface 131. In some embodiments, this results in greatly reduced via resistance.

In one or more embodiments, the barrier layer 160 is selectively deposited by atomic layer deposition (ALD) and has a thickness in a range of from about 2 Å to about 10 Å. In some embodiments, the barrier layer 160 is deposited in a single ALD cycle. In other embodiments, the barrier layer 160 is deposited in from 1 to 20 ALD cycles. In one or more embodiments, each cycle of the 1 to 20 ALD cycles is configured to deposit a thickness of about 0.5 Å of the barrier layer 160.

In a typical ALD process, alternating pulses or flows of “A” precursor and “B” precursor can be used to deposit a film. The alternating exposure of the surface to reactants “A” and “B” is continued until the desired thickness film is reached. However, instead of pulsing the reactants, the gases can flow simultaneously from one or more gas delivery head or nozzle and the substrate and/or gas delivery head can be moved such that the substrate is sequentially exposed to each of the reactive gases. Of course, the aforementioned ALD cycles are merely exemplary of a wide variety of ALD process cycles in which a deposited layer is formed by alternating layers of precursors and co-reactants.

In one or more embodiments, reactants and/or co-reactants are in vapor or gas form. The reactants may be delivered with a carrier gas. A carrier gas, a purge gas, a deposition gas, or other process gas may contain nitrogen, hydrogen, argon, neon, helium, or combinations thereof. The various plasmas described herein, such as the nitrogen plasma or the inert gas plasma, may be ignited from and/or contain a plasma co-reactant gas.

In one or more embodiments, the various gases for the process may be pulsed into an inlet, through a gas channel, from various holes or outlets, and into a central channel. In one or more embodiments, the deposition gases may be sequentially pulsed to and through a showerhead. Alternatively, as described above, the gases can flow simultaneously through gas supply nozzle or head and the substrate and/or the gas supply head can be moved so that the substrate is sequentially exposed to the gases.

In one or more embodiments, the barrier layer material and SAM are deposited using a multi-chamber process with separation of the barrier layer material (e.g., tantalum nitride (TaN)). In other embodiments, a single chamber approach is used, with all processes occurring within one chamber and the different layers/films separated in processing by gas purges.

Some embodiments of the invention are directed to barrier applications, e.g., copper barrier applications. The barrier layer formed by one or more embodiments may be used as a copper barrier. Suitable barrier layers for copper barrier applications include, but are not limited to, TaN and MnN. For copper barrier applications, suitable dopants include, but are not limited to, Ru, Cu, Co, Mn, Al, Ta, Mo, Nb, V, or combinations thereof. A plasma treatment can be used after doping to promote the intermetallic compound formation between the matrix and dopant, as well as removing film impurities and improving the density of the barrier layer. In other embodiments, post treatment can include, but is not limited to, physical vapor deposition (PVD) treatment, thermal anneal, chemical enhancement, or the like. In some copper barrier applications, a high frequency plasma (defined as greater than about 14 MHz or about 40 MHz or greater) can be used with any inert gas, including, but not limited to, one or more of neon (Ne), hydrogen (H₂), and argon (Ar) gas. In one or more embodiments, to prevent low-k damage, a higher plasma frequency can be used (higher than 13.56 MHz). In some embodiments, the barrier layer is a copper barrier and comprises TaN doped with Ru.

Referring to FIG. 1E, in one or more embodiments, the SAM 150 has been removed from the structure shown in FIG. 1D using the methods described herein. In one or more embodiments, removing the SAM 150 comprises a plasma treatment process comprising flowing one or more of hydrogen (H₂) or argon (Ar). In one or more embodiments, the plasma treatment process comprises increasing a density of the barrier layer 160. In one or more embodiments, a gap fill process comprises filling the gap 146 shown in FIG. 1E with one or more of copper (Cu) or cobalt (Co).

FIG. 2 illustrates a process flow diagram of a method 300 for forming a microelectronic device. FIG. 2 illustrates a method of forming any of the microelectronic devices of one or more embodiments shown in FIGS. 1A-1E. Referring to FIG. 2, the method 300 comprises, at operation 310, forming a dielectric layer on a substrate. The dielectric layer comprises at least one feature defining a gap including sidewalls and a bottom. At operation 320, the method 300 comprises pre-cleaning the bottom of the gap, in particular the metal surface 131 to remove impurities from the metal surface 131. At operation 330, the method 300 comprises selectively depositing a self-assembled monolayer (SAM) on the bottom of the gap.

At operation 340, the method 300 comprises forming a barrier layer on the sidewalls 148. At operation 340, the method 300 comprises selectively depositing a barrier layer 160 on the sidewalls 148 of the gap 146. At operation 340, in some embodiments, the barrier layer 160 is deposited at a thickness on the sidewalls but not on the metal surface 131. At operation 350, the method 300 comprises removing the SAM after selectively depositing the barrier layer 160 on the sidewalls 148. At operation 360, the method 300 comprises performing a gap fill process in the gap 146. The gap fill process can include forming one or more of a via and a line to form an interconnect in the device.

In one or more embodiments, the methods described herein comprise an optional post-processing operation. The optional post-processing operation can be, for example, a process to modify film properties (e.g., annealing) or a further film deposition process (e.g., additional ALD or CVD processes) to grow additional films. In some embodiments, the optional post-processing operation can be a process that modifies a property of the deposited film. In some embodiments, the optional post-processing operation comprises annealing the as-deposited film. In some embodiments, annealing is done at temperatures in the range of about 300° C., 400° C., 500° C., 600° C., 700° C., 800° C., 900° C. or 1000° C. The annealing environment of some embodiments comprises one or more of an inert gas (e.g., molecular nitrogen (N₂), argon (Ar)) or a reducing gas (e.g., molecular hydrogen (H₂) or ammonia (NH₃)) or an oxidant, such as, but not limited to, oxygen (O₂), ozone (O₃), or peroxides. Annealing can be performed for any suitable length of time. In some embodiments, the film is annealed for a predetermined time in the range of about 15 seconds to about 90 minutes, or in the range of about 1 minute to about 60 minutes.

In some embodiments, the substrate is moved from a first chamber to a separate, next chamber for further processing. The substrate can be moved directly from the first chamber to the separate processing chamber, or the substrate can be moved from the first chamber to one or more transfer chambers, and then moved to the separate processing chamber. In some embodiments, the deposition of the barrier layer and the dopant film can be done in a single chamber, and then the post-processing can be performed in a separate chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present disclosure are the Centura® and the Endura®, both available from Applied Materials, Inc., of Santa Clara, Calif. However, the exact arrangement and combination of chambers may be altered for purposes of performing specific steps of a process as described herein. Other processing chambers which may be used include, but are not limited to, cyclic deposition including a deposition step, and an annealing or treatment step, atomic layer deposition (ALD), chemical vapor deposition (CVD), physical vapor deposition (PVD), etch, pre-clean, chemical clean, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants (e.g., reactant). According to one or more embodiments, a purge gas is injected at the exit of the deposition chamber to prevent reactants (e.g., reactant) from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, similar to a conveyer system, in which multiple substrates are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

Another aspect of the disclosure pertains to a non-transitory computer readable medium including instructions, that, when executed by a controller of a processing system, causes the processing system to perform operations of the methods described herein. In one embodiment, a non-transitory computer readable medium including instructions, that, when executed by a controller of a processing system, causes the processing system to perform operations of the methods described herein with respect to FIGS. 1A-E and 2.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of forming a microelectronic device, the method comprising:
forming a dielectric layer on a substrate, the dielectric layer comprising at least one feature defining a gap including sidewalls and a bottom including a metal surface;
pre-cleaning the metal surface;
selectively depositing a self-assembled monolayer (SAM) on the bottom of the gap and the metal surface;
selectively depositing a barrier layer on the sidewalls but not on the metal surface; and
removing the SAM after selectively depositing the barrier layer on the sidewalls.

2. The method of claim 1, wherein the substrate is in a substrate processing chamber and the pre-cleaning comprises exposing the metal surface to a cleaning gas selected from H₂O vapor, H₂O₂, WF₆, NH₃, NH₄OH, MoCl₅, MoCl₆, WCl₅, WCl₆, SOCl₂ when the substrate processing chamber is at a temperature of at or above 80° C.

3. The method of claim 2, further comprising exposing the metal surface to a plasma.

4. The method of claim 3, wherein exposing the metal surface to a cleaning gas and to the plasma reduces impurities from the metal surface.

5. The method of claim 4, wherein the impurities are selected from the group consisting of F, Cl, O, N and C.

6. The method of claim 3, wherein selectively depositing the SAM comprises exposing the bottom of the gap to a silane or a hydrocarbon having the formula R₁—C≡C—R₂ or H—C≡C—R₃, wherein R1 and R2 can be the same of different and R1 and R2 are linear alkyl chains having from 1 to 15 carbon atoms and R3 is a linear alkyl chain comprising from 1 to 20 carbon atoms.

7. The method of claim 6, wherein the silane has a formula R—SiH₃, wherein R is selected from a linear alkyl chain and a branched alkyl chain comprising from 2 to 20 carbon atoms.

8. The method of claim 6, wherein the hydrocarbon has the formula R₁—C≡C—R₂—.

9. The method of claim 6, wherein the hydrocarbon has the formula H—C≡C—R₃.

10. The method of claim 6, wherein the hydrocarbon comprises 5-decyne.

11. The method of claim 5, wherein the temperature in the substrate processing chamber during exposing the metal surface to the cleaning gas is in a range of from 200° C. to 400° C.

12. The method of claim 11, wherein the metal surface comprises tungsten and the cleaning gas is selected from H₂O vapor, H₂O₂, WF₆ and exposing metal surface to the cleaning gas occurs for a time from 1 second to 120 seconds.

13. The method of claim 11, wherein the metal surface comprises molybdenum and the cleaning gas is selected from NH₃, NH₄OH, MoCl₅, MoCl₆, WCl₅, WCl₆, SOCl₂, PCl₅ and exposing metal surface to the cleaning gas occurs for a time from 1 second to 240 seconds.

14. The method of claim 4, wherein plasma comprises a remote plasma.

15. The method of claim 14, wherein the plasma comprises inductively coupled plasma.

16. The method of claim 14, wherein the plasma comprises conductively coupled plasma.

17. The method of claim 5, wherein chlorine, oxygen and nitrogen impurities are reduced from the metal surface.

18. The method of claim 5, wherein fluorine impurities are reduced from the metal surface.

19. The method of claim 5, wherein the SAM blocks deposition of the barrier layer on the metal surface.

20. The method of claim 19, wherein the barrier layer comprises TaN.
